(19) United States
(12) Patent Application Publication
(10) Pub. No.: US 2010/0053873 A1
(43) Pub. Date: Mar. 4, 2010

(54) Folding keyboard-and-mouse carrying board of electronic device

(75) Inventor: Don-Hua Cheng, Taichung City (TW)

Correspondence Address: CHARLES E. BAXLEY, ESQUIRE, 90 JOHN STREET, SUITE 309, NEW YORK, NY, 10038, US

(73) Assignee: Hiwin Mikrosystem Corp.

(21) Appl. No.: 12/231,115

(22) Filed: Aug. 28, 2008

(51) Int. Cl. H05K 5/00

(52) U.S. Cl. 361/679.15

(57) ABSTRACT

A folding keyboard-and-mouse carrying board is for being assembled beside a recess formed on a machine body of an electronic device. The folding keyboard-and-mouse carrying board comprises a board connected with the machine body through a link unit so as to allow the recess to be opened or closed thereby. The board has a first surface facing the recess and a second surface at a reverse side of the board with respect to the first surface. A keyboard-positioning unit and a mouse positioning unit are provided at the first surface of the board. A first board-positioning unit positions the board at a retracted position; and a second board-positioning unit positions the board at an expanded position.

### BACKGROUND OF THE INVENTION

1. Technical Field

The present invention relates to electronic devices controlled by computers, and more particularly, to a folding keyboard-and-mouse carrying board of an electronic device, wherein the folding keyboard-and-mouse carrying board serves to position a keyboard and a mouse for operating a computer that controls the electronic device.

2. Description of Related Art

With the rapid progress of technology, computer control mechanisms have been extensively used in electronic devices for various purposes. For the convenience of control, keyboards and mice are typically attached to the electronic devices, wherein such keyboards and mice are usually of universal specifications but not preformed integrally on the electronic devices so as to maximize the application of the keyboards and mice. Meanwhile, since the keyboards and mice require a plane of a certain area for operation, folding carrying boards that can be retracted into or expanded from the electronic devices are conventionally implemented to provide required operational area. However, the conventional folding carrying boards lack structures to position the keyboards and mice. As a result, before the carrying boards are retraced, the keyboards and mice placed thereon must be separately stored so as not to fall by gravity. Hence, a need exists for an improved folding carrying board to remedy the inconvenience of the prior art devices.

### SUMMARY OF THE INVENTION

In view of the aforementioned need, the present invention provides a folding keyboard-and-mouse carrying board that is applicable to an electronic device. The folding keyboard-and-mouse carrying board is capable of being retracted into or expand from a machine body of the electronic device and serves to hold in position a keyboard and a mouse for operating the electronic device so as to secure the keyboard and mouse from accidentally falling off the machine body of the electronic device b by gravity when the folding carrying board is in a retracted position thereof.

To accomplish the aforesaid function, the folding keyboard-and-mouse carrying board of the present invention is for being be assembled beside a recess formed on a machine body of an electronic device and comprises a board, said board being connected with the machine body through a link unit, allowing the recess to be opened or closed to the exterior, and having a first surface facing the recess as well as a second surface at a reverse side of the board with respect to the first surface; a keyboard-positioning unit, provided at the first surface of the board; a mouse positioning unit, provided at the first surface of the board; a first board-positioning unit, serving to position the board at a retracted position; and a second board-positioning unit, serving to position the board at an expanded position.

According to one aspect of the present invention, the link unit between the board and the machine body comprises at least one hinge.

According to one aspect of the present invention, the keyboard-positioning unit comprises at least one pressing clip.

According to one aspect of the present invention, the mouse positioning unit comprises one bracket.

According to one aspect of the present invention, the first board-positioning unit comprises at least one magnetic point and one ferroics area provided on the first surface of the board positionally corresponding to the magnetic point so that when the magnetic point and the ferroics area magnetically combine, the board is positioned at the retraced position.

According to one aspect of the present invention, the first board-positioning unit comprises at least one magnetic point and one ferroics area provided on the first surface of the board corresponding to the magnetic point wherein the ferroics area is made of magnetically attractive stainless steel.

According to one aspect of the present invention, the second board-positioning unit comprises an extendable member settled between the machine body and the first surface of the board, wherein when the extendable member extends to a limit position, the board is positioned at the expanded position.

According to one aspect of the present invention, the second board-positioning unit comprises an extendable member settled between the machine body and the first surface of the board, wherein the extendable member is at least one set of linked rods.

According to one aspect of the present invention, the second board-positioning unit comprises an extendable member settled between the machine body and the first surface of the board, wherein the extendable member is at least one chain.

According to one aspect of the present invention, the second surface of the board is provided with at least one handle.

### BRIEF DESCRIPTION OF THE DRAWINGS

The invention as well as a preferred mode of use, further objectives and advantages thereof, will best be understood by reference to the following detailed description of an illustrative embodiment when read in conjunction with the accompanying drawings wherein:

FIG. 1 is a perspective view of a folding keyboard-and-mouse carrying board of an electronic device according to the present invention, wherein the carrying board is combined with a machine body of the electronic device and is at an expanded position;

FIG. 2 is a schematic drawing of the folding keyboard-and-mouse carrying board according to the present invention, showing a keyboard and a mouse positioned thereon;

FIG. 3 is another perspective view of the folding keyboard-and-mouse carrying board according to the present invention, wherein the carrying board is combined with the machine body of the electronic device and is at a retracted position; and

FIG. 4 is a cross-sectional view of the folding keyboard-and-mouse carrying board combined with the machine body according to the present invention, showing the keyboard and the mouse positioned thereon.

### DETAILED DESCRIPTION OF THE PREFERRED EMBODIMENTS

While a preferred embodiment is provided herein for illustrating the concept of the present invention as described above, it is to be understood that the components in these drawings are made for better explanation and need not to be made in scale. Moreover, in the following description, resemble components are indicated by the same numerals.

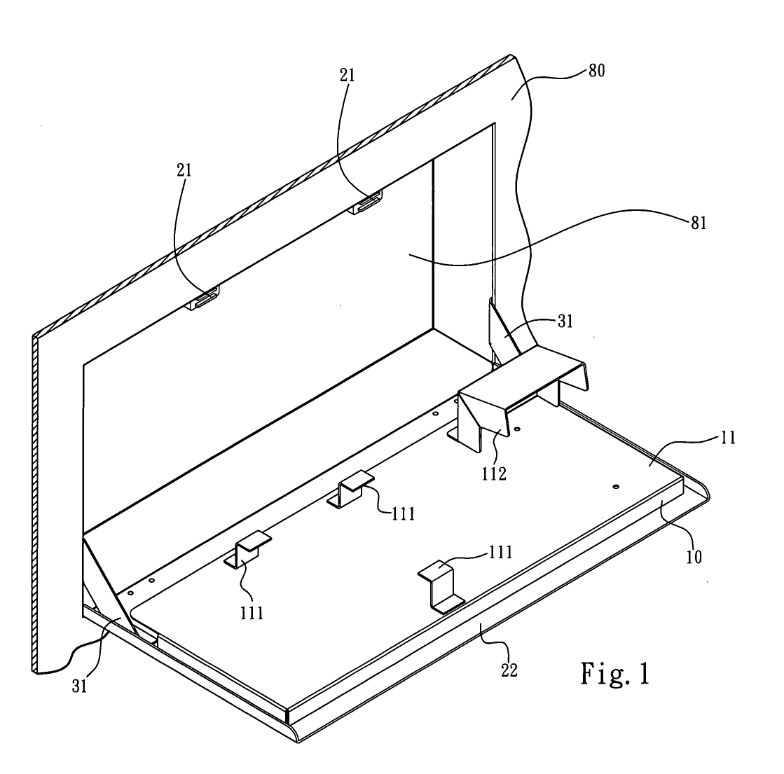

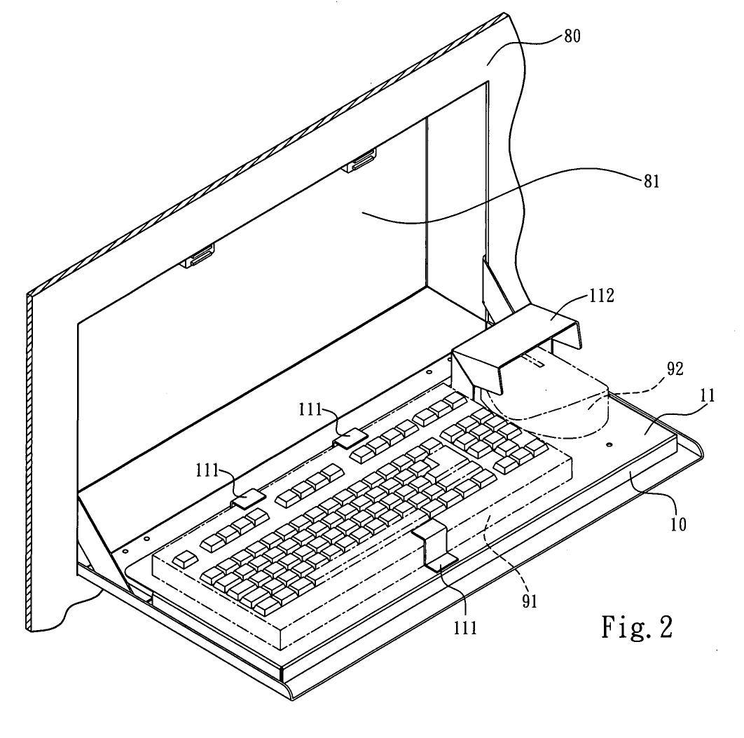

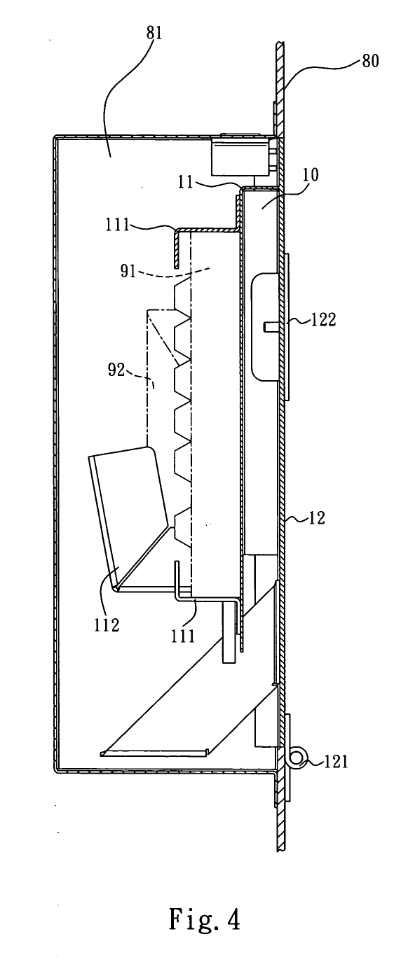

Please refer to FIGS. 1 to 4 for a folding keyboard-and-mouse carrying board that is applicable to an electronic device. The carrying board is assembled beside a recess 81 formed on a machine body 80 of the electronic device. The carrying board comprises a board 10, which is substantially in a rectangular shape. The board 10 has a first surface 11 and a second surface 12. Therein, the first surface 11 faces the recess 81 while the second surface 12 is at a reverse side of the board 10 with respect to the first surface 11.

The board 10 is connected with the machine body 80 of the electronic device through a pair of hinges 121 so that the board 10 is pivotable with respect to the recess 81, and thereby closes or opens the recess 81. Between the board 10 and the machine body 80 of the electronic device, there are a first board-positioning unit and a second board-positioning unit, whose functions and configurations will be given below.

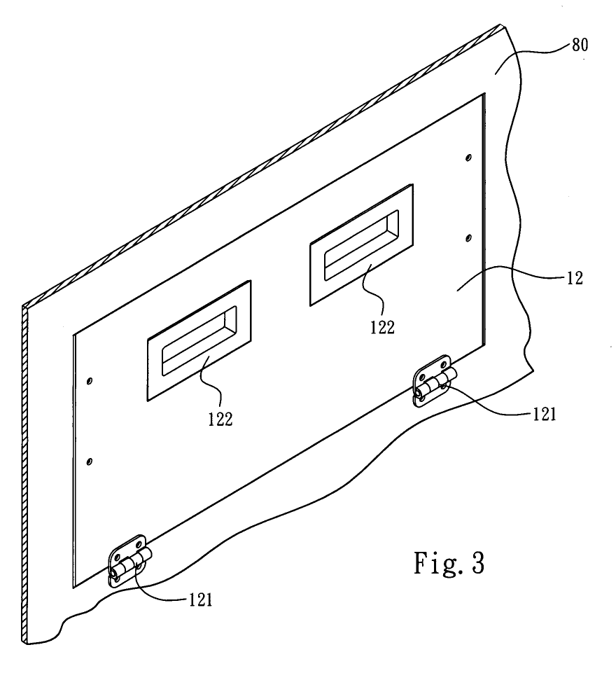

The first board-positioning unit serves to position the board 10 at a retracted position, where the board 10 closes the recess 81. According to the present embodiment, the first board-positioning unit comprises two magnetic points 21 provided on the machine body 80 and one ferroics area 22 provided on the first surface 11 of the board 10 corresponding to the magnetic points 21. The ferroics area 22 may be made of magnetically attractive stainless steel. Therefore, when the magnetic points 21 and the ferroics area 22 magnetically combine, the board is held parallel to a surface of the machine body 80 and has its first surface 11 facing and closing the recess 81 while having its second surface 12 level with the surface of the machine body 80, thereby positioning the board 10 at the retraced position, as shown in FIG. 3.

The second board-positioning unit comprises an extendable member set between the machine body 80 and the first surface 11 of the board 10, wherein the extendable member has a predetermined length and serves to position the board 10 at an expanded position. The extendable member having the predetermined length may be a set of linked rods or a chain. In the embodiment shown in the drawings, two sets of linked rods 31 are employed as the second board-positioning unit. When the linked rods 31 expand to a limit position thereof, the board is substantially perpendicular to the surface of the machine body 80 and positioned at its expanded position, as shown in FIG. 1.

When the board 10 is at the expanded position, as shown in FIG. 1, the board 10 provides its first surface 11 as an operation plane that allows a keyboard and a mouse for controlling a computer (not shown) of the electronic device to be operated thereon. The present invention is characterized in having a keyboard-positioning unit and a mouse positioning unit. According to the present embodiment, the keyboard-positioning unit comprises three pressing clips 111, basing on the principles of “Three points Fixation”, to hold a keyboard 91 stably on., the first surface 11 of the board 10. The a mouse positioning unit comprises one bracket 112 that serves to support and position a mouse 92 when the board 10 is at its retracted position and parallel to the surface of the machine body 80.

Besides, the folding keyboard-and-mouse carrying board of the present invention can further has a pair of handles 122 settled on the second surface 12 of the board 10 so that a user can hold the handles 122 and exert a pulling force to separate the magnetically combined magnetic points 21 and stainless steel strip 22, thereby pulling the board 10 to the expanded position.

The present invention proposes a compact structure that is capable of being retracted into or expanded from an electronic device. The present invention particularly feature holding a keyboard and a mouse placed thereon and secure the keyboard and mouse from falling down when the disclosed carrying board is at its retracted position.

Although the particular embodiment of the invention has been described in detail for purposes of illustration, it will be understood by one of ordinary skill in the art that numerous variations will be possible to the disclosed embodiment without going outside the scope of the invention as disclosed in the claims.

What is claimed is:

1. A folding keyboard-and-mouse carrying board for being assembled beside a recess formed on a machine body of an electronic device, comprising:
a board, connected with the machine body through a link unit so as to allow the recess to be opened or closed thereby, and having a first surface facing the recess as well as a second surface at a reverse side of the board with respect to the first surface;
a keyboard-positioning unit, provided at the first surface of the board;
a mouse positioning unit, provided at the first surface of the board;
a first board-positioning unit, serving to position the board at a retracted position; and
a second board-positioning unit, serving to position the board at an expanded position.

2. The folding keyboard-and-mouse carrying board of claim 1, wherein the link unit between the board and the machine body comprises at least one hinge.

3. The folding keyboard-and-mouse carrying board of claim 1, wherein the keyboard-positioning unit comprises at least one pressing clip.

4. The folding keyboard-and-mouse carrying board of claim 1, wherein the mouse positioning unit comprises one bracket.

5. The folding keyboard-and-mouse carrying board of claim 1, wherein the first board-positioning unit comprises at least one magnetic point and one ferroics area provided on the first surface of the board corresponding to the magnetic point so that when the magnetic point and the ferroics area magnetically combine, the board is positioned at the retraced position.

6. The folding keyboard-and-mouse carrying board of claim 5, wherein the ferroics area is made of magnetically attractive stainless steel.

7. The folding keyboard-and-mouse carrying board of claim 1, wherein the second board-positioning unit comprises an extendable member set between the machine body and the first surface of the board, wherein when the extendable member extends to a limit position, the board is positioned at the expanded position.

8. The folding keyboard-and-mouse carrying board of claim 7, wherein the extendable member is at least one set of linked rods.

9. The folding keyboard-and-mouse carrying board of claim 7, wherein the extendable member is at least one chain.

10. The folding keyboard-and-mouse carrying board of claim 1, wherein the second surface of the board is provided with at least one handle.
